(19) United States
(12) Patent Application Publication
(10) Pub. No.: US 2013/0056752 A1
(43) Pub. Date: Mar. 7, 2013

(54) SILICON CARBIDE SUBSTRATE, SILICON CARBIDE SUBSTRATE MANUFACTURING METHOD, AND SEMICONDUCTOR DEVICE MANUFACTURING METHOD

(71) Applicants: Shinsuke Fujiwara, Itami-shi (JP); Shin Harada, Osaka-shi (JP)

(72) Inventors: Shinsuke Fujiwara, Itami-shi (JP); Shin Harada, Osaka-shi (JP)

(73) Assignee: SUMITOMO ELECTRIC INDUSTRIES, LTD., Osaka-shi (JP)

(21) Appl. No.: 13/599,278

(22) Filed: Aug. 30, 2012

Related U.S. Application Data
(60) Provisional application No. 61/531,225, filed on Sep. 6, 2011.

(30) Foreign Application Priority Data
Sep. 6, 2011 (JP) 2011-193463

(51) Int. Cl. H01L 29/38; H01L 21/78

(52) U.S. Cl. 257/77; 438/460; 257/E29.105; 257/E21.599

(57) ABSTRACT

An edge region has a width of 5 mm. A valid region is surrounded by the edge region, and has an area greater than or equal to 100 cm². At the valid region, a micropipe having a cross-sectional area exceeding 1 μm² is not present. The valid region includes a plurality of high-quality regions occupying 70% or more of the valid region. Each of the plurality of high-quality regions has a square shape, an area greater than or equal to 1 cm², and a micropipe density less than or equal to 1 micropipe per 1 cm².

### BACKGROUND OF THE INVENTION

1. Field of the Invention

The present invention relates to a silicon carbide substrate, a method of manufacturing a silicon carbide substrate, and a method of manufacturing a semiconductor device.

2. Description of the Background Art

In recent years, various studies have been made on the crystal growth method to obtain a silicon carbide substrate having sufficient size and sufficiently low defect. For defect reduction, reducing the micropipe density is particularly an issue.

According to the method exemplified in National Patent Publication No. 2008-515749, seed crystal having the diameter of at least approximately 100 mm is used in crystal growth. This publication teaches that the micropipe density could be reduced down to 7.23 cm⁻². However, the diameter of 100 mm is still too small as compared with the diameter of a silicon substrate used in the industry of the semiconductor field. Moreover, the micropipe density of 7.23 cm⁻² is still too high in the attempt to obtain a semiconductor device of higher reliability.

U.S. Application Publication No. 2004/0187766 proposes using a plurality of single crystal films transferred onto a support substrate as the growing plane. It is asserted that increasing the number of single crystal films can accommodate manufacturing a substrate having a diameter of approximately 300 mm. It is also asserted that the micropipe density can be set to less than or equal to 1 cm⁻².

According to the study carried out by the inventors, it was found that a micropipe having a large cross-sectional area is formed on the border of the plurality of single crystal films in the art disclosed in the aforementioned specification. When a micropipe having a large cross-sectional area, particularly a cross-sectional area exceeding 1 μm², is formed at the silicon carbide substrate, various problems may occur in manufacturing a semiconductor device using such a silicon carbide substrate, despite the small micropipe density. Particularly, leakage through the micropipe may become a problem. Specifically, such great leakage will render difficult the vacuum chucking of the silicon carbide substrate. Furthermore, in a process using liquid, that liquid may pass through the silicon carbide substrate to leak out.

### SUMMARY OF THE INVENTION

In view of the foregoing, an object of the present invention is to provide a silicon carbide substrate having low micropipe density and without a micropipe of large cross-sectional area. Another object of the present invention is to provide a semiconductor device of high reliability.

A silicon carbide substrate of the present invention includes an edge region and a valid region. The edge region has a width of 5 mm. The valid region is surrounded by the edge region, and has an area greater than or equal to 100 cm². The valid region is formed such that a micropipe having a cross-sectional area exceeding 1 μm² is not present. The valid region includes a plurality of high-quality regions occupying 70% or more of the valid region. Each of the plurality of high-quality regions has a rectangular shape, an area greater than or equal to 1 cm², and a micropipe density less than or equal to 1 micropipe per 1 cm².

According to this silicon carbide substrate, a micropipe having a large cross-sectional area is not present in the valid region of the silicon carbide substrate. Accordingly, inconvenience caused by the micropipe in manufacturing a semiconductor device using a silicon carbide substrate can be suppressed. Such inconvenience may be caused by leakage through the micropipe. Such great leakage will render difficult the vacuum chucking of the silicon carbide substrate. Furthermore, in a process using liquid, that liquid may pass through the silicon carbide substrate to leak out.

By manufacturing a semiconductor device using a high-quality region, i.e. a region of low micropipe density, according to the silicon carbide substrate, the reliability of the obtained semiconductor device can be improved.

Preferably, the silicon carbide substrate has a crystal structure of 4H polytype. Accordingly, the physical property of the silicon carbide substrate is rendered favorable.

Preferably, each of the plurality of high-quality regions has the shape of either a square with one side greater than or equal to 1 cm, or a rectangle with a short side greater than or equal to 1 cm. Accordingly, each high-quality region will not have an excessively small dimension. The shape of each high-quality region will be suitable for forming a semiconductor element structure.

Preferably, the in-plane variation of the plane orientation of the silicon carbide substrate is less than 0.2° with respect to one plane orientation. Accordingly, variation in the plane orientation of the silicon carbide substrate becomes smaller.

A silicon carbide substrate of the present invention can be manufactured by the method set forth below. A plurality of single crystal substrates, each having a main surface greater than or equal to 1 cm² in area are prepared. The plurality of single crystal substrates include first to third single crystal substrates. The first single crystal substrate has a main surface surrounded by an outer edge including a first linear segment having a first end. The second single crystal substrate has a main surface surrounded by an outer edge including a second linear segment having a second end. The third single crystal substrate has a main surface surrounded by an outer edge including a third linear segment having third and fourth ends. By combining the main surface of each of the plurality of single crystal substrates to each other, a plurality of single crystal substrate are arranged to constitute one plane having an area greater than or equal to 100 cm². The step of arranging a plurality of single crystal substrates is carried out such that the first to third single crystal substrates are adjacent to each other at the first to third linear segments, the first and the second ends meet at one point, the one point is located on the third linear segment, and the one point is located apart from each of the third and fourth ends. By depositing silicon carbide through sublimation on the one plane, single crystal silicon carbide is grown on the one plane. Then, the single crystal silicon carbide is sliced.

According to the method of manufacturing a silicon carbide substrate, the border where the first and second linear segments overlap and extend among the boundaries between the single crystal substrates runs against the section of the third linear segment extending linearly. Accordingly, the borders take a T shape. If the borders take a cross shape, a cavity that becomes the origin of generating a large micropipe is readily formed at the center of the cross shape. The T-shape border is advantageous in that such a cavity is not readily formed, which in turn suppresses generation of a large micropipe.

Preferably, each of the plurality of single crystal substrates has a hexagonal crystal structure. More preferably, the crystal structure is of the 4H polytype. Accordingly, the physical property of the silicon carbide substrate is rendered favorable.

Preferably, a side face of the first single crystal substrate including the first linear segment and a side face of the second single crystal substrate including the second linear segment each have an inclination greater than or equal to 5° to an m plane. More preferably, the component of the inclination about the c axis is greater than or equal to 5°. Accordingly, generation of a micropipe having a large cross-sectional area at the border between the first and second single crystal substrates can be suppressed.

Preferably, each of the plurality of single crystal substrates has the shape of either a square with one side greater than or equal to 1 cm, or a rectangle with a short side greater than or equal to 1 cm. Accordingly, each single crystal substrate will not have an excessively small dimension. By growing silicon carbide on the single crystal substrate, the shape of the high-quality region obtained will be suitable for forming a semiconductor element structure.

Preferably, the main surface of each of the plurality of single crystal substrates has an inclination less than 0.2° to the one plane orientation. Accordingly, variation in the plane orientation of the silicon carbide substrate is reduced.

Preferably, the outer edge of the one plane is trimmed after the step of arranging a plurality of single crystal substrates and before the step of growing single crystal silicon carbide. Accordingly, a plurality of single crystal substrates corresponding to seed crystal can take a predetermined configuration.

A method of manufacturing a semiconductor device according to the present invention includes the following steps. A silicon carbide substrate is prepared. The silicon carbide substrate includes an edge region and a valid region. The edge region has a width of 5 mm. The valid region is surrounded by the edge region, and has an area greater than or equal to 100 cm². The valid region is formed to avoid the presence of a micropipe exceeding 1 μm² in cross-section. The valid region includes a plurality of high-quality regions occupying 70% or more of the valid region. Each of the plurality of high-quality regions has a rectangular shape, an area greater than or equal to 1 cm², and a micropipe density less than or equal to 1 micropipe per 1 cm². A plurality of semiconductor element structures are formed by forming at least one semiconductor element structure on each of the plurality of high-quality regions at the silicon carbide substrate. The silicon carbide substrate is diced such that the plurality of semiconductor element structures are separated from each other.

According to a method of manufacturing a semiconductor device, a semiconductor device is manufactured using the silicon carbide substrate set forth above. Accordingly, inconvenience caused by the micropipe in manufacturing a semiconductor device can be suppressed. Furthermore, the reliability of the semiconductor device can be improved since a semiconductor element structure is formed in the high-quality region of the silicon carbide substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically representing a configuration of a silicon carbide substrate according to a first embodiment of the present invention.

FIG. 2 is a plan view schematically representing a first step in a method of manufacturing a silicon carbide substrate according to the first embodiment of the present invention.

FIG. 3 is a partial enlarged view of the silicon carbide substrate of FIG. 2.

FIG. 4 is a plan view schematically representing a second step in the method of manufacturing a silicon carbide substrate according to the first embodiment of the present invention.

FIGS. 5-7 are sectional views schematically representing third to fifth steps, respectively, in the method of manufacturing a silicon carbide substrate according to the first embodiment of the present invention.

FIG. 8 is a plan view representing one step in the method of manufacturing a silicon carbide substrate of a comparative example.

FIGS. 9 and 10 are partial enlarged views of the silicon carbide substrate of FIGS. 8 and 9, respectively.

FIG. 11 is a plan view schematically representing a modification of FIG. 1.

FIG. 12 is a sectional view schematically representing a configuration of a semiconductor device according to a second embodiment of the present invention.

FIG. 13 is a flowchart schematically representing a method of manufacturing a semiconductor device according to the second embodiment of the present invention.

FIG. 14 is a flowchart schematically representing the step of forming a semiconductor element structure of FIG. 13.

FIGS. 15-18 are sectional views schematically representing first to fourth steps, respectively, in a method of manufacturing a semiconductor device according to the second embodiment of the present invention.

### DESCRIPTION OF THE PREFERRED EMBODIMENTS

Embodiments of the present invention will be described hereinafter based on the drawings.

As to the crystallographic definitions in the present specification, the individual orientation is represented by [ ], the group orientation by < >, the individual plane by ( ), and the group plane by { }. For a negative index, a negative sign is applied before the numeral in the present specification although generally a bar (−) is attached above the numeral in crystallographic expressions.

### First Embodiment

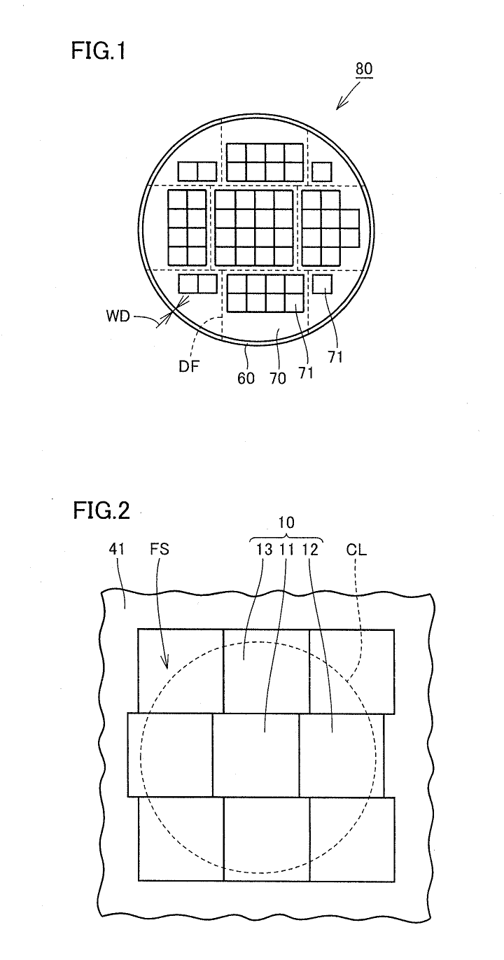

As shown in FIG. 1, a silicon carbide substrate 80 of the present embodiment is formed of silicon carbide having a single crystal structure. Preferably, the crystal structure is of the 4H polytype. Silicon carbide substrate 80 has an area greater than or equal to 100 cm². Preferably, silicon carbide substrate 80 has a circle shape, as shown in FIG. 1, with a diameter greater than or equal to 120 mm, for example. A notch or orientation flat may be provided at silicon carbide substrate 80. Preferably, the in-plane variation of the plane orientation at silicon carbide substrate 80 is less than 0.2° with respect to one plane orientation.

Silicon carbide substrate 80 includes an edge region 60 and a valid region 70. The border between edge region 60 and valid region 70 is virtual, and does not necessarily have to be observable.

Edge region 60 is the portion located at the rim of silicon carbide substrate 80. The quality of edge region 60 is generally of no concern in manufacturing a semiconductor device using silicon carbide substrate 80. The width WD of edge region 60 is 5 mm. In FIG. 1, edge region 60 has an annular shape.

Valid region 70 is surrounded by edge region 60. A micropipe having a cross-sectional area exceeding 1 μm² is not present in valid region 70. Valid region 70 includes a plurality of high-quality regions 71 occupying 70% or more of valid region 70. In valid region 70, the border between the portion of high-quality region 71 and another portion is virtual, and does not necessarily have to be observable.

Each high-quality region 71 has a micropipe density less than or equal to 1 micropipe per 1 cm². Each high-quality region 71 has a rectangular shape, and an area greater than or equal to 1 cm². Preferably, each high-quality region 71 has the shape of either a square with one side greater than or equal to 1 cm, or a rectangle with a short side greater than or equal to 1 cm. In the present embodiment, each high-quality region 71 corresponds to a square having one side greater than or equal to 1 cm. Furthermore, the shapes of all high-quality regions 71 are equal to each other.

A portion DF that has a relatively high micropipe density may be present between high-quality regions 71 in valid region 70. Although a micropipe exceeding a cross-sectional area of 1 μm² is not present in portion DF, the density of micropipes having a cross-sectional area less than or equal to 1 μm² is higher than that of high-quality region 71, and the density may exceed 1 micropipe per 1 cm². Portion DF typically extends linearly, and may be observable more clearly by applying wet etching.

A method of manufacturing silicon carbide substrate 80 will be described hereinafter.

As shown in FIG. 2, a plurality of single crystal substrates 10, each having a main surface greater than or equal to 1 cm² in area are prepared. Single crystal substrates 10 include first to third single crystal substrates 11-13. Each single crystal substrate 10 preferably has a hexagonal crystal structure, more preferably a 4H polytype crystal structure. Further preferably, the main surface of each single crystal substrate 10 has an inclination less than 0.2° to one plane orientation. Further preferably, each single crystal substrate 10 takes the shape of either a square with one side greater than or equal to 1 cm, or a rectangle with a short side greater than or equal to 1 cm. FIG. 2 corresponds to the case where 9 single crystal substrates 10 are prepared.

Then, by combining the main surfaces of each of the plurality of single crystal substrates 10, the plurality of single crystal substrates 10 are arranged to constitute a plane FS (one plane) having an area greater than or equal to 100 cm². Specifically, a plurality of single crystal substrates 10 are arranged on a mount 41. Mount 41 is formed of a heat-resistant material, preferably a material that can have a solid state stably at 1800° C., more preferably, a material that can have a solid state stably at 2100° C., such as graphite. Each single crystal substrate 10 and mount 41 may be fastened by an adhesive such as a carbon-based adhesive.

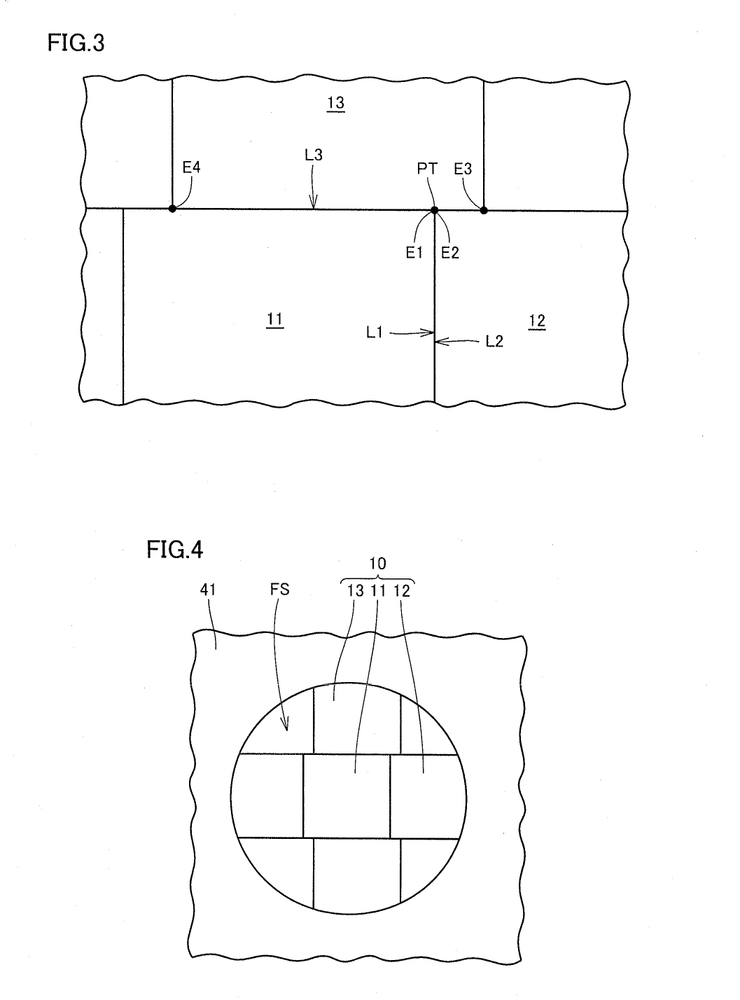

As shown in FIG. 3, first single crystal substrate 12 is provided with a main surface surrounded by an outer edge including a first linear segment L1 having a first end E1. Second single crystal substrate 12 is provided with a main surface surrounded by an outer edge including a second linear segment L2 having a second end E2. Third single crystal substrate 13 is provided with a main surface surrounded by an outer edge including a third linear segment L3 having third and fourth ends E3 and E4. Preferably, the side face of first single crystal substrate 11 including first linear segment L1 and the side face of second single crystal substrate 12 including second linear segment L2 each have an inclination greater than or equal to 5° to an m plane. More preferably, the component of the inclination about the c axis is greater than or equal to 5°. The m plane is the {10-10} plane in hexagonal crystal.

By arranging a plurality of single crystal substrate 10, first to third single crystal substrates 11-13 are adjacent to each other at first-third linear segments L1-L3. Furthermore, at a point PT (one point), first end E1 and second end E2 meet. Point PT is located on third linear segment L3.

As used herein, “adjacent” implies that any gap between the substrates is substantially eliminated. This gap is preferably less than or equal to 100 μm, more preferably less than or equal to 20 μm. Furthermore, “first end E1 and second end E2 meeting at point PT (one point)” implies that each of first end E1 and second end E2 substantially overlap at point PT. In other words, there is substantially no difference in distance between each of first and second ends E1 and E2 and point PT″. This distance is less than or equal to 100 μm, more preferably less than or equal to 20 μm. “Point PT located on third linear segment L3” implies that the distance between point PT and third linear segment L3 is substantially eliminated. This distance is less than or equal to 100 μm, more preferably less than or equal to 20 μm.

Point PT is located apart from each of third end E3 and fourth end E4. In other words, point PT is apart from each of third end E3 and fourth end E4 by at least a predetermined distance. This distance is preferably greater than or equal to 0.2 mm, more preferably greater than or equal to 1 mm. As a result, linear segments L1 and L3 constitute a T-shaped border. Preferably, a T-shaped border is formed at all the sections where three or more single crystal substrates 10 are adjacent. FIG. 2 corresponds to such a case.

The outer edge of plane FS may be trimmed along a line CL (FIG. 2). This trimming is carried out by laser work, for example.

As shown in FIG. 4, a desired outer edge shape is applied to plane FS by the aforementioned trimming.

As shown in FIG. 5, raw material 51 directed to forming single crystal silicon carbide by sublimation is placed in a crucible 42. For example, crucible 42 is a graphite crucible, and raw material 51 is silicon carbide powder. Mount 41 is attached such that each single crystal substrate 10 faces inward of crucible 42. As shown in FIG. 5, mount 41 may also serve as a lid of crucible 42.

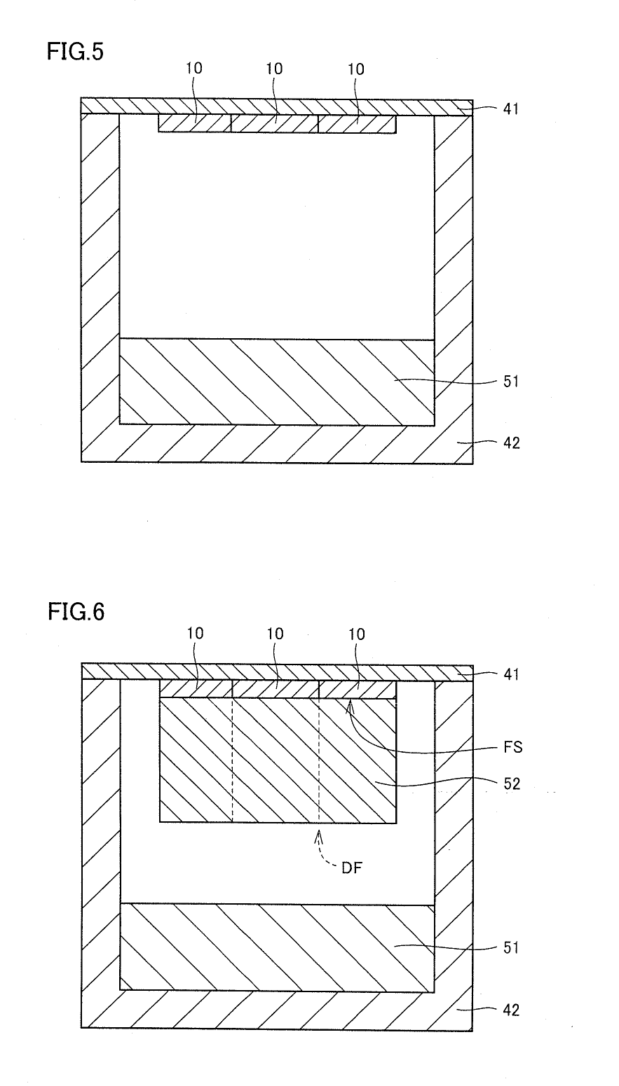

As shown in FIG. 6, single crystal silicon carbide 52 is grown on plane FS by depositing silicon carbide on plane FS by sublimation. By sublimating raw material 51, and recrytallizing the sublimed gas, single crystal silicon carbide 52 is grown epitaxially on plane FS. Single crystal silicon carbide 52 is formed to span the border of adjacent single crystal substrates 10. The region on this border readily becomes a portion DF where the micropipe density is higher than that of other portions.

The temperature in the sublimation method is set greater than or equal to 2100° C. and less than or equal 2500° C., for example. The pressure in the sublimation method is preferably set greater than or equal to 1.3 kPa and less than or equal to the atmospheric pressure, more preferably less than or equal to 13 kPa to increase the growing rate.

Then, mount 41 is taken out from crucible 42.

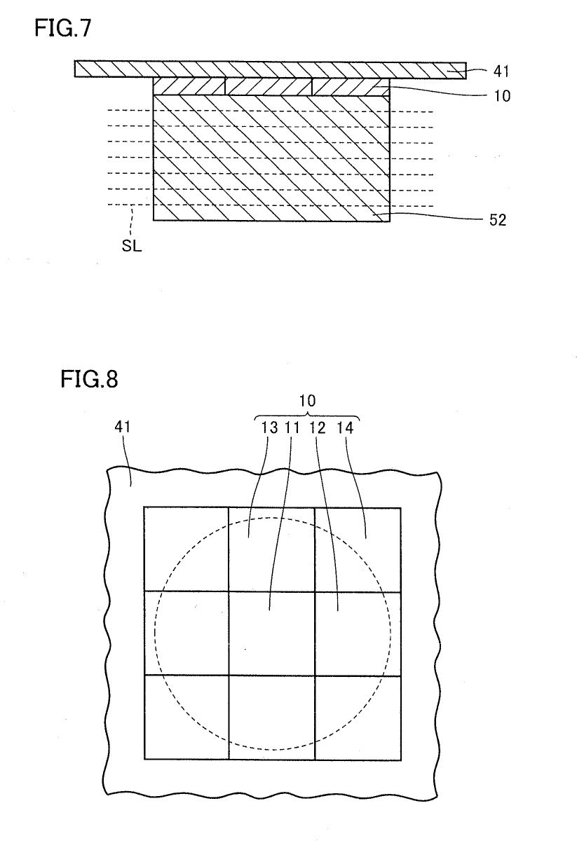

As shown in FIG. 7, single crystal silicon carbide 52 is sliced along the desired plane orientation represented by a broken line SL. Thus, silicon carbide substrate 80 is obtained from single crystal silicon carbide 52.

A comparative example for the present embodiment will be described hereinafter.

As shown in FIG. 8, a plurality of single crystal substrates 10 including first to fourth single crystal substrates 11-14 are arranged in matrix on mount 41. In the ideal manner, single crystal substrates 10 are arranged such that first to fourth single crystal substrates 11-14 form a cross-shaped border. In this case, first to third ends E1-E3 of first to third single crystal substrates 11-13, respectively, meet at point PT (one point). However, in practice, a void VD will be formed at the site where first to fourth single crystal substrates 11-14 abut against each other, as shown in FIG. 10, due to an error in the dimension or arrangement of single crystal substrate 10. Therefore, if a single crystal silicon carbide is grown using single crystal substrates 10 arranged in such a manner as the seed crystal, a micropipe having a large cross-sectional area exceeding 1 μm² will be formed with void VD as the origin.

According to silicon carbide substrate 80 of the present embodiment, a micropipe having a large cross-sectional area is not present in valid region 70 of silicon carbide substrate 80. Accordingly, inconvenience caused by a micropipe in the manufacturing step of a semiconductor device using silicon carbide substrate 80 can be suppressed. This inconvenience particularly occurs by the leakage through the micropipe. Such a large leakage will render difficult the vacuum chucking of silicon carbide substrate 80. Furthermore, in a process using liquid, that liquid may pass through silicon carbide substrate 80 to leak out.

According to silicon carbide substrate 80 set forth above, the reliability of a semiconductor device can be improved by manufacturing a semiconductor device using a plurality of high-quality regions 71, i.e. regions having a low micropipe density.

Preferably, silicon carbide substrate 80 has the 4H polytype crystal structure. Accordingly, the physical property of silicon carbide substrate 80 is rendered favorable.

Preferably, each of high-quality regions 71 has the shape of either a square with one side greater than or equal to 1 cm, or a rectangle with a short side greater than or equal to 1 cm. Accordingly, each high-quality region 71 will not have an excessively small dimension. The shape of each high-quality region 71 will be suitable for forming a semiconductor element structure.

Preferably, the in-plane variation orientation of the plane orientation at silicon carbide substrate 80 is less than 0.2° with respect to one plane orientation. Accordingly, variation in the plane orientation of silicon carbide substrate 80 is reduced.

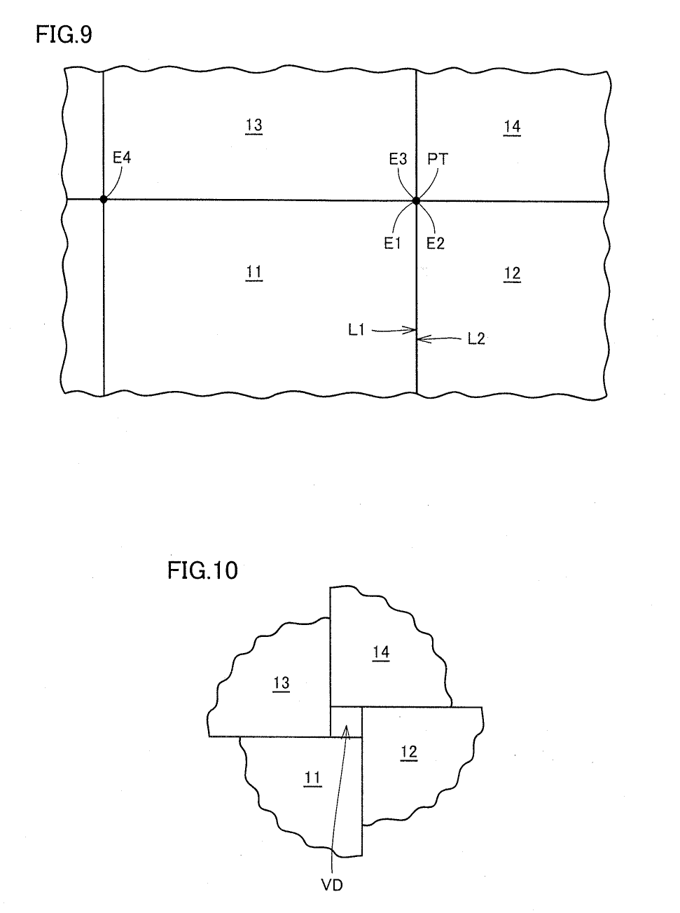

According to the method of manufacturing silicon carbide substrate 80 of the present embodiment, the border where first and second linear segments L1 and L2 overlap and extend, among the borders of single crystal substrates, runs against a section of third linear segments L3 extending linearly. Accordingly, the border takes a T shape. In the case where the border takes a cross shape (FIG. 9), a void (FIG. 10) that becomes the origin of generating a micropipe is readily formed. By virtue of the border having a T shape in the present embodiment, void VD is less likely to be formed. Thus, generation of a large micropipe can be suppressed.

Preferably, each of the plurality of single crystal substrate 10 has a hexagonal crystal structure. More preferably, the crystal structure is of the 4H polytype. Accordingly, the physical property of silicon carbide substrate 80 is rendered favorable.

Preferably, the side face of first single crystal substrate 11 and second single crystal substrate 12 including first linear segment L1 and second linear segment L2, respectively, (FIG. 3) each have an inclination greater than or equal to 5° to an m plane. More preferably, the component of the inclination about the c axis is greater than or equal to 5°. Accordingly, generation of a micropipe having a large cross-sectional area at the border between the first and second single crystal substrates 11 and 12 can be suppressed.

Preferably, each single crystal substrate 10 has the shape of either a square with one side greater than or equal to 1 cm, or a rectangle with a short side greater than or equal to 1 cm. Accordingly, each single crystal substrate will not have an excessively small dimension. By growing silicon carbide on each single crystal substrate 10, the shape of high-quality region 71 obtained will be suitable for forming a semiconductor element structure.

Preferably, the main surface of each of the plurality of single crystal substrates 10 has an inclination less than 0.2° to the one plane orientation. Accordingly, variation in the plane orientation of the silicon carbide substrate is reduced.

Preferably, the outer edge of plane FS is trimmed (broken line CL in FIG. 2) after the step of arranging a plurality of single crystal substrates 10 and before the step of growing single crystal silicon carbide 52. Accordingly, a plurality of single crystal substrates 10 corresponding to seed crystal can take a predetermined configuration.

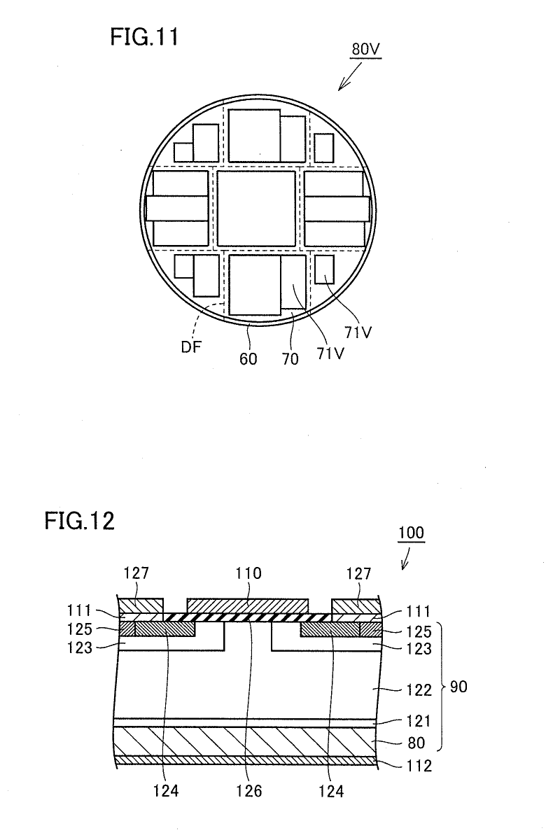

FIG. 1 corresponds to the case where each high-quality region 71 corresponds to a square, and all high-quality regions 71 have a shape equal to each other. In this case, formation of a semiconductor structure with respect to each high-quality region 71 is facilitated. However, the form of the high-quality region is not limited thereto. For example, as shown in FIG. 11, a plurality of high-quality regions 71V having a shape differing from each other may be provided at a silicon carbide substrate 80V.

### Second Embodiment

As shown in FIG. 12, a metal oxide semiconductor field effect transistor (MOSFET) (semiconductor device) 100 of the present embodiment is a vertical type DiMOSFET (Double Implanted MOSFET). MOSFET 100 includes an epitaxial substrate 90, a gate insulating film 126, a source electrode 111, an upper source electrode 127, a gate electrode 110, and a drain electrode 112. Epitaxial substrate 90 includes a silicon carbide substrate 80, a buffer layer 121, a breakdown voltage holding layer 122, a p region 123, an n⁺ region 124 and a p⁺ region 125.

Silicon carbide substrate 80 and buffer layer 121 are of n conductivity type. The concentration of the n type conduction impurities in buffer layer 121 is 5×10¹⁷ cm⁻³, for example. The thickness of buffer layer 121 is 0.5 μm, for example.

Breakdown voltage holding layer 122 is formed on buffer layer 121, made of n conductivity type silicon carbide. For example, the thickness of breakdown voltage holding layer 122 is 10 μm, and the concentration of the n type conduction impurities is 5×10¹⁵ cm⁻³.

At the surface of breakdown voltage holding layer 122, a plurality of p regions 123 having p type conductivity are formed spaced apart from each other. In and at the surface layer of p region 123, an n⁺ region 124 is formed. A p⁺ region 125 is formed adjacent to n⁺ region 124. Gate insulating film 126 is formed on a region of breakdown voltage holding layer 122 exposed between p regions 123. Specifically, gate insulating film 126 is formed extending from above n⁺ region 124 at one of p regions 123, over p region 123, a region of breakdown voltage holding layer 122 exposed between two p regions 123, the other p region 123, as far as above n⁺ region 124 at the relevant other p region 123. Gate electrode 110 is formed on gate insulating film 126. Source electrode 111 is formed on n⁺ region 124 and p⁺ region 125. Upper source electrode 127 is formed on source electrode 111.

The maximum value of the nitrogen atom concentration at a region within 10 nm from the boundary between gate insulating film 126 and the semiconductor layer including n⁺ region 124, p⁺ region 125, p region 123 and breakdown voltage holding layer 122 is greater than or equal to 1×10²¹ cm⁻³. Accordingly, the mobility at the channel region particularly under gate insulating film 126 (the region in contact with gate insulating film 126 and the portion of p region 123 located between n⁺ region 124 and breakdown voltage holding layer 122).

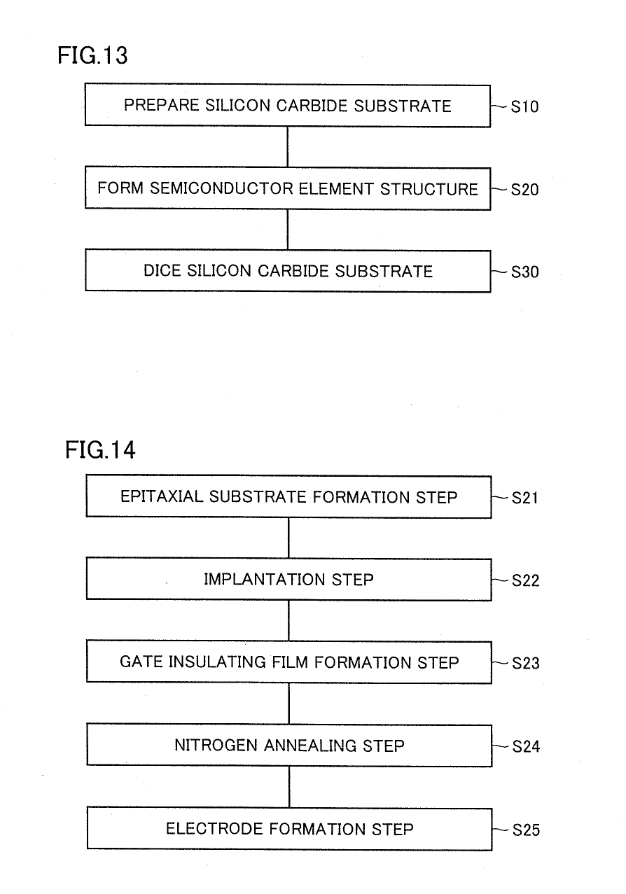

A method of manufacturing MOSFET 100 will be described hereinafter. First, silicon carbide substrate 80 (FIG. 1) is prepared by the method described in the first embodiment (step S10 (FIG. 13)). Then, by forming at least one semiconductor element structure (a structure corresponding to one semiconductor chip) on each of high-quality regions 71 (FIG. 1) of silicon carbide substrate 80, a plurality of semiconductor element structures are formed (step S20) FIG. 13)). This step S20 will be described in further detail hereinafter.

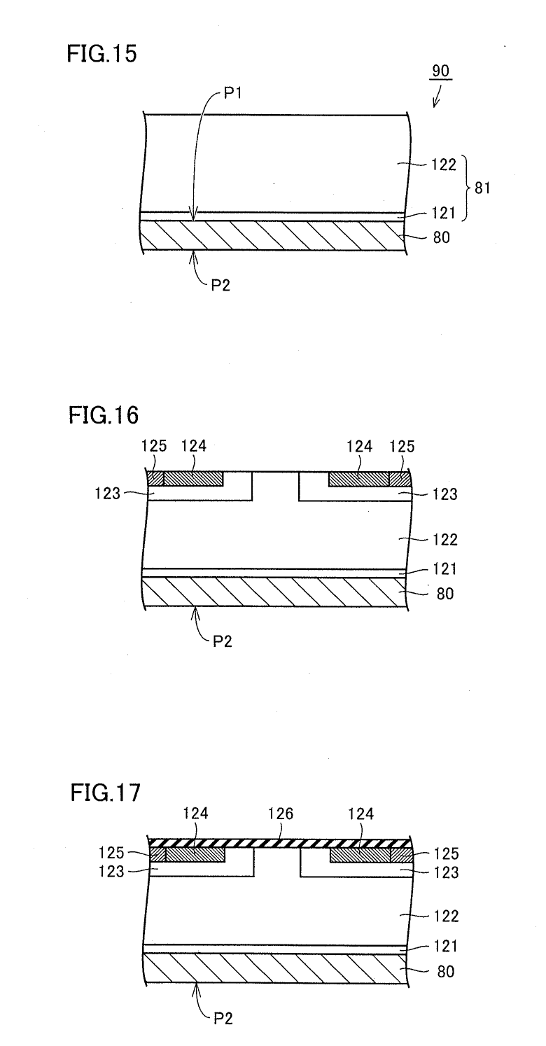

As shown in FIG. 15, an epitaxial layer 81 is formed on a surface P1 of silicon carbide substrate 80. Specifically, buffer layer 121 is formed on silicon carbide substrate 80. A breakdown voltage holding layer 122 is formed on buffer layer 121. Accordingly, an epitaxial substrate 90 is formed (step S21 (FIG. 14)). Buffer layer 121 is formed of n conductivity type silicon carbide, having a thickness of 0.5 μm, for example. The conduction impurity concentration at buffer layer 121 is 5×10¹⁷ cm⁻³. The thickness of breakdown voltage holding layer 122 is 10 μm, for example. The n type conduction impurity concentration of breakdown voltage holding layer 122 is 5×10¹⁵ cm⁻³, for example.

As shown in FIG. 16, p region 123, n⁺ region 124 and p⁺ region 125 are formed by an implantation step (step S22 (FIG. 14)), as set forth below.

By selectively implanting p type conduction impurities to a region of breakdown voltage holding layer 122, p type region 123 is formed. Then, by selectively introducing n type conduction impurities into a predetermined region, n⁺ region 14 is formed. By selectively introducing p type conduction impurities into a predetermined region, p⁺ region 125 is formed. Selective introduction of impurities is carried out using a mask made of oxide film, for example. The patterning of the oxide film mask may be carried out by photolithography.

The exposure in photolithography on a substrate of a relatively large size is often carried out over a plurality of times, instead of being completed at one time. In other words, a plurality of regions of the substrate are often sequentially exposed. The region corresponding to the exposure-by-exposure basis is preferably one or a plurality of high-quality regions 71.

Following the implantation step, activation annealing is carried out. For example, annealing is carried out for 30 minutes at the heating temperature of 1700° C. in an argon atmosphere, for example.

As shown in FIG. 17, a gate insulating film formation step (step S23 (FIG. 14)) is carried out. Specifically, gate insulating film 126 is formed to cover breakdown voltage holding layer 122, p region 123, n⁺ region 124, and p⁺ region 125. This formation may be carried out by dry oxidation (thermal oxidation). The dry oxidation condition includes, for example, a heating temperature of 1200° C. and a heating time of 30 minutes.

Then, a nitride annealing step (step S24 (FIG. 14)) is carried out. Specifically, annealing is carried out in a nitrogen oxide (NO) atmosphere. The processing conditions include, for example, a heating temperature of 1100° C. and a heating time of 120 minutes. As a result, nitrogen atoms are introduced in the proximity of the boundary between gate insulating film 126 and each of breakdown voltage holding layer 122, p region 123, n⁺ region 124 and p⁺ region 125. Following this annealing step using nitrogen oxide, an annealing process using argon (Ar) gas that is inert gas may be carried out. The processing conditions include, for example, a heating temperature of 1100° C. and a heating time of 60 minutes.

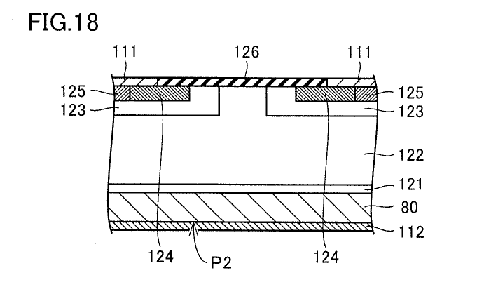

As shown in FIG. 18, by an electrode formation step (step S25 (FIG. 14)), source electrode 111 and drain electrode 112 are formed as set forth below.

On gate insulating film 126, a resist film having a pattern is formed by photolithography. Using this resist film as a mask, the region of gate insulating film 126 located above n⁺ region 124 and p⁺ region 125 is removed by etching. Accordingly, an opening is formed at gate insulating film 126. At this opening, a conductor film is formed to be brought into contact with each of n⁺ region 124 and p⁺ region 125. Then, by removing the resist film, the region of the aforementioned conductor film located on the resist film is removed (lift off). The conductor film may be a metal film, for example nickel (Ni). As a result of the lift off, source electrode 111 is formed.

At this stage, heat treatment is preferably carried out for alloying. For example, heat treatment is carried out for 2 minutes at the heating temperature of 950° C. in an atmosphere of argon (Ar) gas that is inert gas.

As shown in FIG. 12, upper source electrode 127 is formed on source electrode 111. Also, gate electrode 110 is formed on gate insulating film 126. Furthermore, drain electrode 112 is formed on the back face P2 of silicon carbide substrate 80.

Thus, step S20 (FIG. 13) is completed.

Then, silicon carbide substrate 80 is diced such that a plurality of semiconductor chips are separated from each other. For example, in the case where one semiconductor chip is formed at each of high-quality regions 71, dicing is carried out such that high-quality regions 71 are separated from each other. In the case where a plurality of semiconductor chips are formed at each of high-quality regions 71, high-quality regions 71 are separated, not only from each other, but also into a group of high-quality regions 71, by dicing.

Thus, MOSFET 100 is obtained.

According to the method of manufacturing a semiconductor device of the present embodiment, an MOSFET 100 is manufactured using silicon carbide substrate 80 set forth above. Since a micropipe having a cross-sectional area exceeding 1 μm² is not present in valid region 70 (FIG. 1) of silicon carbide substrate 80, inconvenience caused by a large micropipe during the manufacturing of an MOSFET can be suppressed. For example, in the case where a vacuum chuck is used for securing silicon carbide substrate 80 during the manufacturing process, insufficient fastening of silicon carbide substrate 80 caused by leakage through the large micropipe can be avoided. Furthermore, during the photolithography process, the chemical agent used in the exposure or development process can be prevented from leaking through the large micropipe.

Since the micropipe density of high-quality region 71 (FIG. 1) at silicon carbide substrate 80 is less than or equal to 1 micropipe per 1 cm², the density of micropipes present at MOSFET 100 can be reduced. Accordingly, the reliability of MOSFET 100 can be improved.

A configuration in which the conductivity types are interchanged, i.e. the p type and n type exchanged, may be employed. Furthermore, although the description is based on MOSFET 100, the semiconductor device may be a metal insulator semiconductor FET (MISFET) other than a MOSFET. Moreover, the semiconductor device is not limited to a MOSFET, and may be an IGBT (Insulated Gate Bipolar Transistor) or a JFET (Junction FET).

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide substrate, comprising:
an edge region having a width of 5 mm, and
a valid region surrounded by said edge region, and having an area greater than or equal to 100 cm²,
said valid region being formed such that a micropipe having a cross-sectional area exceeding 1 μm² is not present,
said valid region including a plurality of high-quality regions occupying 70% or more of said valid region, and
each of said plurality of high-quality regions having a rectangular shape, an area greater than or equal to 1 cm², and a micropipe density less than or equal to 1 micropipe per 1 cm².

2. The silicon carbide substrate according to claim 1, wherein said silicon carbide substrate has a 4H polytype crystal structure.

3. The silicon carbide substrate according to claim 1, wherein each of said plurality of high-quality regions has a shape of one of
a square with one side greater than or equal to 1 cm, and
a rectangle with a short side greater than or equal to 1 cm.

4. The silicon carbide substrate according to claim 1, wherein in-plane variation of plane orientation of said silicon carbide substrate is less than 0.2° to one plane orientation.

5. A method of manufacturing a silicon carbide substrate, comprising the steps of:
preparing a plurality of single crystal substrates, each including a main surface having an area greater than or equal to 1 cm²,
said plurality of single crystal substrates including a first single crystal substrate provided with a main surface surrounded by an outer edge including a first linear segment having a first end, a second single crystal substrate provided with a main surface surrounded by an outer edge including a second linear segment having a second end, and a third single crystal substrate provided with a main surface surrounded by an outer edge including a third linear segment having third and fourth ends, and
arranging said plurality of single crystal substrates to constitute one plane having an area greater than or equal to 100 cm² by combining said main surface of each of said plurality of single crystal substrates with each other,
said step of arranging said plurality of single crystal substrates is performed such that said first to third single crystal substrates are adjacent to each other at said first to third linear segments, such that said first end and said second end meet at one point, such that said one point is located on said third linear segment, and such that said one point is located apart from each of said third end and said fourth end, and
growing single crystal silicon carbide on said one plane by depositing silicon carbide on said one plane by sublimation method, and
slicing said single crystal silicon carbide.

6. The method of manufacturing a silicon carbide substrate according to claim 5, wherein each of said plurality of single crystal substrates has a hexagonal crystal structure.

7. The method of manufacturing a silicon carbide substrate according to claim 6, wherein said crystal structure is of 4H polytype.

8. The method of manufacturing a silicon carbide substrate according to claim 6, wherein a side face of said first single crystal substrate including said first linear segment and a side face of said second single crystal substrate including said second linear segment each have an inclination greater than or equal to 5° to an m-plane.

9. The method of manufacturing a silicon carbide substrate according to claim 8, wherein a component of said inclination about a c-axis is greater than or equal to 5°.

10. The method of manufacturing a silicon carbide substrate according to claim 5, wherein each of said plurality of single crystal substrates has a shape of one of
a square with one side greater than or equal to 1 cm, and
a rectangle with a short side greater than or equal to 1 cm.

11. The method of manufacturing a silicon carbide substrate according to claim 5, wherein said main surface of each of said plurality of single crystal substrates has an inclination less than 0.2° to one plane orientation.

12. The method of manufacturing a silicon carbide substrate according to claim 5, further comprising the step of trimming an outer edge of said one plane after said step of arranging said plurality of single crystal substrates and before said step of growing single crystal silicon carbide.

13. A method of manufacturing a silicon carbide semiconductor device, comprising the steps of:
preparing a silicon carbide substrate,
said silicon carbide substrate including an edge region having a width of 5 mm, and a valid region being surrounded by said edge region and having an area greater than or equal to 100 cm², said valid region being formed such that a micropipe having a cross-sectional area exceeding 1 μm² is not present, said valid region including a plurality of high-quality regions occupying 70% or more of said valid region, and each of said plurality of high-quality regions having a rectangular shape, an area greater than or equal to 1 cm², and a micropipe density less than or equal to 1 micropipe per 1 cm², and
forming a plurality of semiconductor element structures by forming at least one semiconductor element structure on each of said plurality of high-quality regions of said silicon carbide substrate, and
dicing said silicon carbide substrate such that said plurality of semiconductor element structures are separated from each other.

14. The method of manufacturing a silicon carbide semiconductor device according to claim 13, wherein said silicon carbide substrate has a 4H polytype crystal structure.

15. The method of manufacturing a silicon carbide substrate according to claim 13, wherein each of said plurality of high-quality regions has a shape of one of
a square with one side greater than or equal to 1 cm, and
a rectangle with a short side greater than or equal to 1 cm.

16. The method of manufacturing a silicon carbide substrate according to claim 13, wherein in-plane variation of plane orientation of said silicon carbide substrate is less than 0.2° to one plane orientation.
